(19) United States
(12) Patent Application Publication
(10) Pub. No.: US 2003/0224604 A1
(43) Pub. Date: Dec. 4, 2003

(54) Sacrificial polishing substrate for improved film thickness uniformity and planarity

(75) Inventor: Joe Cho, Belmont, CA (US)

Correspondence Address: Pillsbury Winthrop LLP, Intellectual Property Group, Suite 2800, 725 South Figueroa Street, Los Angeles, CA, 90017-5406, US

(73) Assignee: Intel Corporation, Santa Clara, CA

(21) Appl. No.: 10/160,610

(22) Filed: May 31, 2002

(51) Int. Cl. H01L 21/302; H01L 21/461

(52) U.S. Cl. 438/692

(57) ABSTRACT

A method and apparatus for planarizing semiconductor wafers utilized a sacrificial substrate. The sacrificial substrate, in the form of a sacrificial ring or a sacrificial disc, allows the wafer to sit flush inside the sacrificial substrate. The sacrificial substrate acts as a sacrificial extension of the wafer to be polished and experiences the edge roll-off effect during the polishing process instead of the wafer to be polished. As a result, the wafer to be polished has improved flatness and film thickness uniformity due to shifting the edge roll-off effects beyond the edge of the wafer to be polished outwards to the sacrificial substrate.

### BACKGROUND

1. Technical Field

The present invention generally relates to polishing semiconductor wafers. More particularly, the present invention relates to chemical-mechanical polishing of films that have been deposited on semiconductor wafers.

2. Discussion of the Related Art

Integrated circuits (IC) are mass-produced by the fabrication of identical circuit patterns on a single semiconductor wafer. A series of wafer masking and processing steps are used to fabricate each IC. The IC's are fabricated from various materials, including conductors (e.g., copper, aluminum and tungsten), non-conductors (e.g., silicon dioxide), and semiconductors (e.g., silicon).

Within an IC, thousands of devices (e.g., transistors, diodes) are formed. Typically, contacts are formed where a device interfaces to an area of doped silicon. Specifically, plugs are typically formed to connect metal layers with device active regions. Vias are typically formed to connect metal layers with other metal layers. Also, interconnects are typically formed to serve as wiring lines to interconnect the devices on the IC and the many regions within an individual device. These contacts and interconnects are formed using conductive materials.

The IC devices with their various conductive layers, semiconductive layers, insulating layers, contacts and interconnects are formed by fabrication processes, including doping processes, deposition processes, photolithographic processes, etching processes, etc.

During IC manufacturing, the various masking and processing steps typically result in the formation of topographical irregularities on the wafer surface. For example, topographical surface irregularities are created after metallization, which includes a sequence of blanketing the wafer surface with a conductive metal layer and then etching away unwanted portions of the blanket metal layer to form a metallization interconnect pattern on the IC. A common surface irregularity is known as a step which results from the resulting height differential between the metal interconnect and the wafer surface where the metal has been removed.

Since these geometries are photolithographically produced, it is important that the wafer surface be highly planar in order to accurately focus the illumination radiation at a single plane of focus to achieve precise imaging over the entire surface of the wafer. A wafer surface that is not sufficiently planar will result in structures that are poorly defined, with the circuits either being nonfunctional or, at best, exhibiting less than optimum performance.

To alleviate these problems, the wafer is “planarized” at various points in the process to minimize non-planar topography and its adverse effects. As additional levels are added to multilevel-interconnection schemes and circuit features are scaled to submicron dimensions, the required degree of planarization increases. As circuit dimensions are reduced, interconnect levels must be globally planarized to produce a reliable, high-density device. Planarization can be implemented on either the conductor or the dielectric layers.

One common technique to planarize a wafer is known as chemical mechanical polishing (CMP). In general, CMP processing involves holding and pressing semiconductor wafers against a polishing pad mounted to a rotating turntable in the presence of a polishing solution (slurry). A conventional rotational CMP apparatus (see FIG. 1) includes a polishing head for holding a semiconductor wafer. The wafer is typically mounted with the surface to be polished exposed, on a wafer carrier, which is part of or attached to a polishing head. The polishing head is designed to be continuously rotated by a drive mechanism. In addition, the polishing head typically is also designed for transverse movement. The rotational and transverse movement is intended to reduce variability in material removal rates over the surface of the wafer.

The CMP apparatus further includes a rotating platen on which is mounted the polishing pad. The platen is relatively large in comparison to the wafer, so that during the CMP process, the wafer may be moved across the surface of the polishing pad by the polishing head. A polishing slurry containing chemically-reactive solution, in which are suspended abrasive particles, is deposited through a supply tube onto the surface of the polishing pad.

CMP is a well-developed planarization technique. The underlying chemistry and physics of the technique are understood. Certain limitations, however, exist with CMP. Specifically, the CMP process suffers from an inherent non-uniformity of the polishing surface between the center of the surface that is polished and the perimeter of the surface that is polished. During polishing, the pliability of the polishing pad tends to wrap around the edges of the wafer. As a result, the pad pressure is applied to a smaller area near the edges and causes a higher polishing rate at the edges relative to the center. The higher polishing rate produces non-uniformity in the film thickness, which could impact subsequent lithography processes and eventually edge die yield. The significance of mitigating polishing edge roll-off effects will grow as the wafer diameter grows for future technologies.

Therefore, there is a need for a method and device for polishing semiconductor wafers in a uniform manner, that eliminates polishing differences between the center of the wafer that is being polished and areas of the surface that extend toward the perimeter of the wafer surface.

### BRIEF DESCRIPTION OF THE DRAWINGS

FIG. 1 illustrates a prior art conventional rotational Chemical Mechanical Polishing (CMP) apparatus;

FIG. 2a illustrates a rotational CMP apparatus including a sacrificial ring according to an embodiment of the present invention;

FIG. 2b illustrates a rotational CMP apparatus including a sacrificial disc according to an embodiment of the present invention;

FIG. 3 illustrates a comparison of wafer profiles according to an embodiment of the present invention;

FIG. 4 illustrates a method of manufacturing a sacrificial ring according to an embodiment of the present invention; and

FIG. 5a-d illustrates a method of manufacturing an integrated circuit according to an embodiment of the present invention.

### DETAILED DESCRIPTION

An embodiment of the present invention is targeted to improve the film thickness uniformity and planarity, especially along the edge of the wafer. One of the issues seen in the polishing area for IC manufacturing is the non-uniform film thickness and poor planarity due to edge roll-off effects caused by high polishing rates at the edge of the wafer relative to the center.

A sacrificial substrate in the form of a sacrificial ring, whose inner diameter matches that of the outer diameter of the wafer to be polished, allows the wafer to sit flush inside the ring and allows the sacrificial ring to act as the sacrificial extension of the wafer to be polished. Therefore, the sacrificial ring experiences the edge roll-off instead of the wafer to be polished. As a result, the wafer to be polished has an improved flatness and film thickness uniformity by shifting the edge roll-off effects beyond the edge of the wafer to be polished outwards to the sacrificial ring.

An alternative embodiment of the present invention uses a sacrificial substrate in the form of a sacrificial disk having a recessed pocket cut out of a center of the sacrificial disc, a diameter of the recessed pocket being approximately equal to a diameter of a wafer to be polished, and a depth of the recessed pocket being approximately equal to a thickness of the wafer to be polished. The recessed pocket allows the wafer to sit flush inside the sacrificial disc and allows a polishing surface of the sacrificial disc to act as the sacrificial extension of the wafer to be polished. Therefore, the polishing surface of the sacrificial disc experiences the edge roll-off instead of the wafer to be polished. As a result, the wafer to be polished has an improved flatness and film thickness uniformity by shifting the edge roll-off effects beyond the edge of the wafer to be polished outwards to the polishing surface of the sacrificial disc.

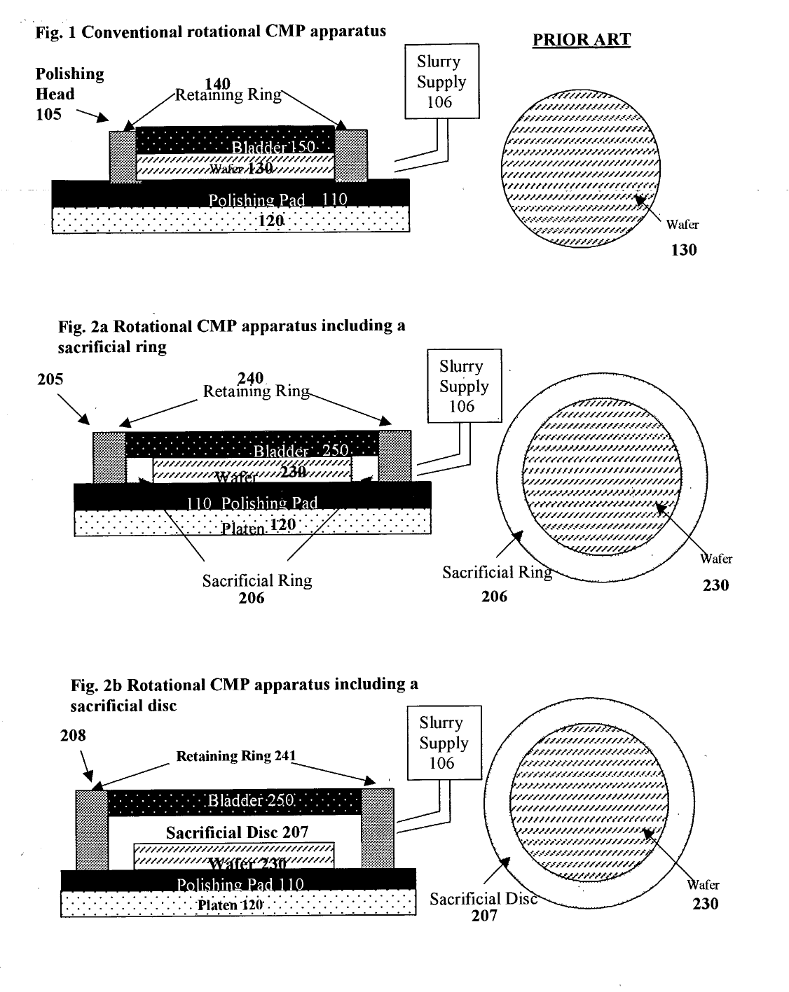

FIG. 1 illustrates a conventional rotational Chemical Mechanical Polishing (CMP) apparatus 100. The polishing head assembly 105 consists of a retaining ring 140, bladder 150 and wafer 130. The polishing pad 110 sits on top of the platen 120 while the wafer 130 fits inside the retaining ring 140, with the bladder 150 exerting downward pressure against the wafer 130 to maintain contact between the wafer 130 and the polishing pad 110. The retaining ring 140 acts as a “holder” to prevent the wafer 130 from sliding off the polishing pad 110 during the polishing process. The slurry supply 106 dispenses polishing slurry.

FIG. 2a illustrates a polishing apparatus with a polishing head 205 including a sacrificial ring 206, according to an embodiment of the present invention. The polishing head assembly 205 is larger in diameter to accommodate the sacrificial ring 206 plus the wafer 230 to be polished. The polishing head assembly 205 consists of a retaining ring 240, bladder 250, sacrificial ring 206 and wafer 230. The polishing pad 110 sits on top of the platen 120 while the wafer 230 fits inside the sacrificial ring 206, which fits inside the retaining ring 240. The bladder 250 exerting downward pressure against the wafer 230 and the sacrificial ring 206 to maintain contact between the wafer 230 and the polishing pad 110. The retaining ring 240 acts as a “holder” to prevent the sacrificial ring 206 with the wafer 230 from sliding off the polishing pad 110 during the polishing process.

An alternate embodiment of the present invention uses a sacrificial disc 207 in place of the sacrificial ring 206. FIG. 2b illustrates a polishing apparatus with a polishing head 208 including a sacrificial disc 207 according to an alternate embodiment of the present invention. The polishing head assembly 208 is larger in diameter to accommodate the sacrificial disc 207 plus the wafer 230 to be polished. The polishing head assembly 208 includes of a retaining ring 241, bladder 250, sacrificial disc 207, and wafer 230. The polishing pad 110 sits on top of the platen 120 while the wafer 230 fits inside a recessed pocket in the sacrificial disc 207, which fits inside the retaining ring 241. The bladder 250 exerting downward pressure against the sacrificial disc 207 and wafer 230 to maintain contact between the wafer 230 and the polishing pad 110. The retaining ring 241 acts as a “holder” to prevent the sacrificial disc 207 plus wafer 230 from sliding off the polishing pad 110 during the polishing process.

A sacrificial substrate, in the form of a sacrificial ring 206 or a sacrificial disc 207, allows the wafer 230 to sit flush inside the sacrificial ring 206 or sacrificial disc 207 and allows the sacrificial ring 206 or sacrificial disc 207 to act as the sacrificial extension of the wafer 230 to be polished. Therefore, the sacrificial ring 206 or sacrificial disc 207 experiences the edge roll-off effect instead of the wafer 230 to be polished. As a result, the wafer 230 to be polished has an improved flatness and film thickness uniformity by shifting the edge roll-off effects beyond the edge of the wafer 230 to be polished outwards to the sacrificial ring 206 or sacrificial disc 207.

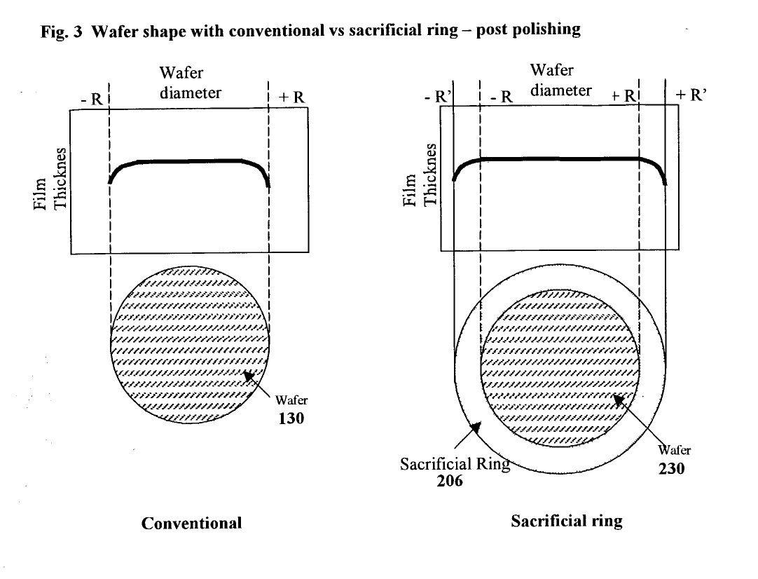

FIG. 3 shows the difference in planarity and film thickness uniformity using the sacrificial ring 206 of an embodiment of the present invention vs. the conventional approach. The graphs illustrate the expected wafer profile after polishing. The center of the wafers are flat except the edges roll off due to enhanced edge polishing rate near −R and +R for the conventional approach and −R′ and +R′ for the sacrificial ring 206 approach. The graph also shows that the wafer 230 is polished flat even at −R and +R for the sacrificial ring 206 approach because the impact of the enhanced polishing rate has shifted to the sacrificial ring 206 instead of the wafer 230 itself. The sacrificial disc 207 yields similar results.

The ability to control the edge-polishing rate with the current conventional approach is extremely difficult and has not been successful. As an alternative approach, the sacrificial substrate in the form of a sacrificial ring 206 or a sacrificial disc 207 proves useful, for example, for 300-mm diameter wafers and even larger diameter wafers 230.

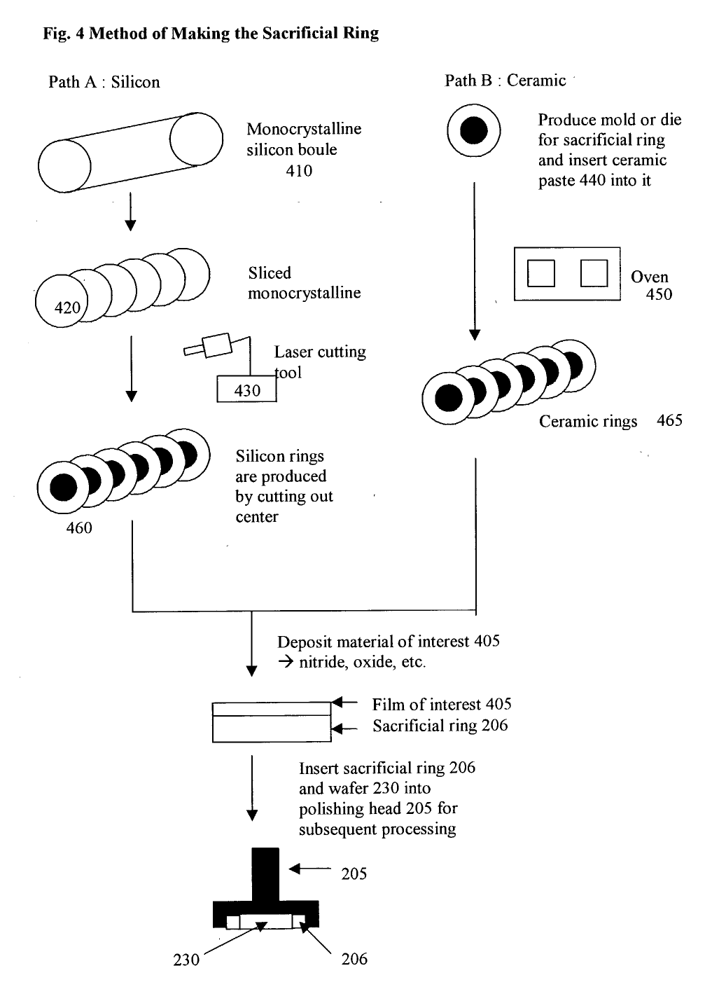

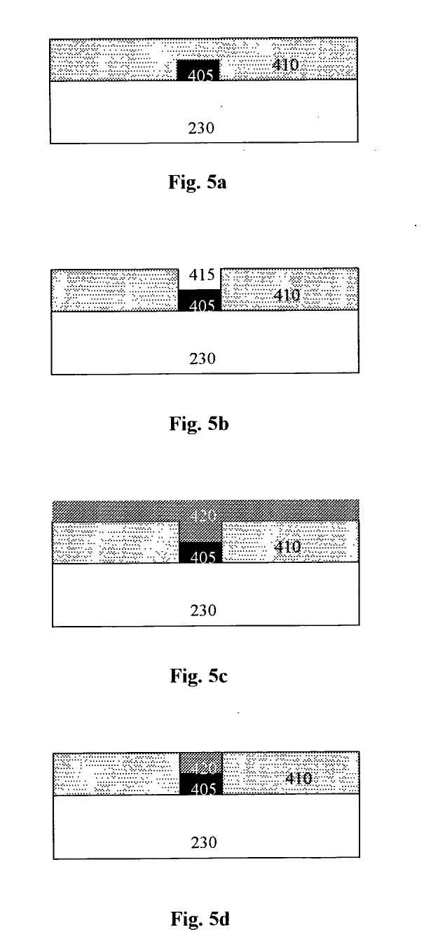

FIG. 4 illustrates a method of manufacturing a sacrificial ring 206. The substrate for the sacrificial ring 206 may be made of nearly any durable material. According to embodiments of the present invention, two materials may be used: silicon and ceramic. Silicon is the most commonly used semiconductor, and may be used in either its single crystal or polycrystalline form.

The fabrication of integrated circuit devices begins by producing semiconductor wafers cut from a boule of single crystal silicon that is formed by pulling a seed from a silicon melt rotating in a crucible. The boule is then sliced into individual wafers using a diamond-cutting blade. Polycrystalline silicon is often referred to as polysilicon or “poly”.

In path A, the substrate is illustratively silicon and the silicon boule 410 is produced through standard industry practices with Czochralski bulk growth. The wafers 420 are sliced again through standard practices with wire saw technology. The center of the wafers 420 may be cut out with a precision laser cutting tool 430 such that the inner diameter of the sacrificial ring 206 matches the diameter of the wafer 230 to be polished (150 mm, 200 mm, 300 mm wafers, etc.) to produce a silicon ring 460. The diameter of the boule 410 is generally greater than that of the wafer 230 to be polished, but within the range of manufacturability. The cost is lower since the boule 410 does not have to be monocrystalline. The sacrificial disc 207 may be manufactured in a similar manner, wherein the diameter of the recessed pocket matches the diameter of the wafer 230 to be polished, and the depth of the recessed pocket of the sacrificial disc 207 matches the thickness of the wafer 230 to be polished.

In path B, the sacrificial ring 206 substrate may also be manufactured out of ceramics. A paste 440 is formed and filled into a mold or die. The material is then fired in an oven 450 through industry standard practices to produce ceramic rings 465. The sacrificial disc 207 may be manufactured in a similar manner.

Finally, the silicon ring 460 or ceramic ring 465 is deposited with the same material 405 that the polishing process intends to remove from the wafer 230 to be polished so as to maintain consistent polishing performance characteristics. The material 405 may be, for example, a thin film deposited by a vacuum deposition. The total thickness of the sacrificial ring 206 matches the total thickness of the wafer 230 to be polished (within ±10 μm) to preserve polishing planarity. The sacrificial disc 207 may be manufactured in a similar manner, wherein the depth of the recessed pocket of the sacrificial disc 207 matches the total thickness of the wafer 230 to be polished (within ±10 μm).

FIG. 5a-d illustrates a method of manufacturing an integrated circuit. A semiconductor device 405 is formed on a wafer to be polished 230 with a first dielectric layer 410 formed over the surface of the wafer to be polished 230. A first opening 415 is formed in the first dielectric layer 410, where the first opening 415 exposes the semiconductor device 405. A conductive material 420 is deposited over the first dielectric layer 410 filling the first opening 415. A sacrificial substrate 206, 207 (see FIGS. 2a & 2b) is selected with a conductive material deposited on a polishing surface that is same as the conductive material 420 deposited over the first dielectric layer 410 filling the first opening 415 on the wafer to be polished 230.

Referring to FIGS. 2a and 2b, the wafer to be polished 230 is mounted in the sacrificial substrate 206, 207, the sacrificial substrate 206, 207 and the wafer to be polished 230 are mounted into the retaining ring 240, 241 contained within the polishing head 205, 208. The polishing head 205, 208 containing the wafer to be polished 230, the sacrificial substrate 206, 207, and the retaining ring 240, 241 are positioned on a polishing pad 110 mounted to a rotating platen 120. A polishing slurry 106 is applied to the rotating polishing pad 110 and the wafer to be polished 230 is polished to remove an amount of the conductive material 420 deposited on the wafer to be polished 230 to expose the first dielectric layer 410 and provide a planar polished surface of the conductive material 420 (see FIGS. 5c & 5d). A measurement may be made to determine the amount of the conductive material 420 that is removed from the wafer to be polished 230. The measurement may include determining a flatness of the wafer to be polished (see FIG. 3).

A sacrificial substrate, in the form of a sacrificial ring 206 or a sacrificial disc 207, allows the wafer 230 to sit flush inside the sacrificial ring 206 or sacrificial disc 207 and allows the sacrificial ring 206 or sacrificial disc 207 to act as the sacrificial extension of the wafer 230 to be polished. Therefore, the sacrificial ring 206 or sacrificial disc 207 experiences the edge roll-off effect instead of the wafer 230 to be polished. As a result, the wafer 230 to be polished has an improved flatness and film thickness uniformity by shifting the edge roll-off effects beyond the edge of the wafer 230 to be polished outwards to the sacrificial ring 206 or sacrificial disc 207.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes that come within the meaning and range of equivalency of the claims are therefore intended to be embraced therein.

What is claimed is:

1. A sacrificial ring, comprising:
a substrate formed in a ring shape, wherein an inner diameter of the substrate is slightly larger than an outer diameter of a wafer to be polished, and the wafer to be polished fits flush inside the substrate.

2. The sacrificial ring according to claim 1, wherein the substrate is made from a same type of material as the wafer to be polished.

3. The sacrificial ring according to claim 1, wherein the substrate is a ceramic material.

4. The sacrificial ring according to claim 1, wherein the substrate is a semiconductor material.

5. The sacrificial ring according to claim 1, wherein a-thickness of the substrate is substantially equal to a thickness of the wafer to be polished.

6. The sacrificial ring according to claim 1, wherein the substrate and the wafer to be polished have a layer of material deposited on a polishing surface.

7. A sacrificial disc, comprising:
a substrate formed in a disc shape, wherein the substrate includes a recessed pocket, and a wafer to be polished fits flush inside the recessed pocket of the substrate.

8. The sacrificial disc according to claim 7, wherein the substrate is made from a same type of material as the wafer to be polished.

9. The sacrificial disc according to claim 7, wherein the substrate is a ceramic material.

10. The sacrificial disc according to claim 7, wherein the substrate is a semiconductor material.

11. The sacrificial disc according to claim 7, wherein a diameter of the recessed pocket is slightly larger than a diameter of the wafer to be polished, and a depth of the recessed pocket is substantially equal to a thickness of the wafer to be polished.

12. The sacrificial disc according to claim 7, wherein a thickness of the substrate is greater than a thickness of the wafer to be polished.

13. The sacrificial disc according to claim 7, wherein the substrate and the wafer to be polished have a layer of material deposited on a polishing surface.

14. A polishing machine, comprising:
a polishing table;
a polishing pad on the polishing table;
a slurry supplier to supply a slurry onto the polishing table to polish a wafer;
a retaining ring;
a sacrificial substrate; and
a polishing head, to dispose of the retaining ring, the sacrificial substrate, and the wafer therein, wherein the wafer is retained by the sacrificial substrate, the sacrificial substrate is retained by the retaining ring, and the retaining ring is contained in the polishing head such that a wafer surface and a sacrificial substrate surface to be polished are facing the polishing pad.

15. The polishing machine of claim 14, wherein the sacrificial substrate is a sacrificial ring.

16. The polishing machine of claim 15, wherein the retaining ring has an inner diameter slightly larger than an outer diameter of the sacrificial ring, and the sacrificial ring has an inner diameter slightly larger than an outer diameter of the wafer.

17. The polishing machine of claim 14, wherein the sacrificial substrate is a sacrificial disc.

18. The polishing machine of claim 17, wherein the sacrificial disc includes a recessed pocket, a diameter of the recessed pocket is slightly larger than a diameter of the wafer, and a depth of the recessed pocket is substantially equal to a thickness of the wafer.

19. The polishing machine of claim 14, wherein the retaining ring has a plurality of slurry passages to direct the slurry supplied by the slurry supplier through the retaining ring over the wafer surface and the sacrificial substrate surface to be polished.

20. A method of manufacturing a sacrificial ring, comprising:
slicing a rod shaped substrate to produce a plurality of wafers;
cutting a circle out of a center of the plurality of wafers to form a plurality of sacrificial rings, a diameter of the circle being approximately equal to a diameter of a wafer to be polished; and
depositing a material on a first surface of the plurality of sacrificial rings, wherein the material deposited is same as a material to be polished on the wafer to be polished.

21. The method of claim 20, wherein slicing includes using a wire saw or a diamond cutting blade.

22. The method of claim 20, wherein cutting includes using a precision laser cutting tool.

23. The method of claim 20, wherein a thickness of the sacrificial ring substantially equals a thickness of the wafer to be polished.

24. The method of claim 20, wherein the material deposited is a thin film deposited by a vacuum deposition.

25. The method of claim 20, wherein a thickness of the material deposited substantially equals a thickness of the material to be polished on the wafer to be polished.

26. A method of manufacturing a sacrificial ring, comprising:
forming a paste and filling a mold of a sacrificial ring with the paste; firing the mold including the paste to form a sacrificial ring; and
depositing a material on a first surface of the sacrificial ring, wherein the material deposited is same as a material to be polished on a wafer to be polished.

27. The method of claim 26, wherein the paste includes a ceramic paste.

28. The method of claim 26, wherein a thickness of the sacrificial ring substantially equals a thickness of the wafer to be polished.

29. The method of claim 26, wherein the material deposited is a thin film deposited by a vacuum deposition.

30. The method of claim 26, wherein a thickness of the material deposited substantially equals a thickness of the material to be polished on the wafer to be polished.

31. A method of manufacturing a sacrificial disc, comprising:
slicing a rod shaped substrate to produce a plurality of wafers;
cutting a recessed pocket out of a center of the plurality of wafers to form a plurality of sacrificial discs, a diameter of the recessed pocket being approximately equal to a diameter of a wafer to be polished, and a depth of the recessed pocket being approximately equal to a thickness of the wafer to be polished; and
depositing a material on a first surface of the plurality of sacrificial discs, wherein the material deposited is same as a material to be polished on the wafer to be polished.

32. The method of claim 31, wherein slicing includes using a wire saw or a diamond cutting blade.

33. The method of claim 31, wherein cutting includes using a precision laser cutting tool.

34. The method of claim 31, wherein a thickness of the sacrificial disc is greater than the thickness of the wafer to be polished.

35. The method of claim 31, wherein the material deposited is a thin film deposited by a vacuum deposition.

36. The method of claim 31, wherein a thickness of the material deposited substantially equals a thickness of the material to be polished on the wafer to be polished.

37. A method of manufacturing a sacrificial disc, comprising:
forming a paste and filling a mold of a sacrificial disc with the paste;
firing the mold including the paste to form a sacrificial disc; and
depositing a material on a first surface of the sacrificial disc, wherein the material deposited is same as a material to be polished on a wafer to be polished.

38. The method of claim 37, wherein the paste includes a ceramic paste.

39. The method of claim 37, wherein a thickness of the sacrificial disc is greater than a thickness of the wafer to be polished.

40. The method of claim 37, wherein the sacrificial disc includes a recessed pocket, a diameter of the recessed pocket being slightly larger than a diameter of the wafer to be polished, and a depth of the recessed pocket being substantially equal to a thickness of the wafer to be polished.

41. The method of claim 37, wherein the material deposited is a thin film deposited by a vacuum deposition.

42. The method of claim 37, wherein a thickness of the material deposited substantially equals a thickness of the material to be polished on the wafer to be polished.

43. A method of manufacturing an integrated circuit, comprising:
providing a semiconductor device formed on a wafer to be polished with a first dielectric layer formed thereon;
forming a first opening in the first dielectric layer, said forming the first opening exposing the semiconductor device;
depositing a conductive material over said first dielectric layer and filling said first opening;
selecting a sacrificial substrate with a conductive material deposited on a polishing surface that is same as the conductive material deposited over the first dielectric layer filling the first opening on the wafer to be polished;
mounting the wafer to be polished in the sacrificial substrate, and mounting the sacrificial substrate and the wafer to be polished into a retaining ring contained within a polishing head;
positioning the polishing head containing the wafer to be polished, the sacrificial substrate, and the retaining ring on a polishing pad mounted to a rotating platen;
applying a polishing slurry to the rotating polishing pad; and
polishing the wafer to be polished to remove an amount of the conductive material deposited on the wafer to be polished to expose the first dielectric layer and provide a planar polished surface of the conductive material.

44. The method according to claim 43, wherein a measurement is made to determine the amount of the conductive material that is removed from the wafer to be polished.

45. The method according to claim 44, wherein the measurement includes determining a flatness of the wafer to be polished.

46. The method according to claim 43, wherein filling the first opening with conductive material uses a material selected from a group consisting of copper, aluminum, silver, gold, alloys thereof, and combinations thereof.
